(19) United States
(12) Patent Application Publication
(10) Pub. No.: US 2013/0134977 A1
(43) Pub. Date: May 30, 2013

(54) MAGNETIC RESONANCE APPARATUS

(71) Applicant: GE Medical Systems Global Technology Co. LLC, Waukesha, WI (US)

(72) Inventor: Yuji Iwadate, Tokyo (JP)

(73) Assignee: GE MEDICAL SYSTEMS GLOBAL TECHNOLOGY COMPANY, LLC, Waukesha, WI (US)

(21) Appl. No.: 13/687,847

(22) Filed: Nov. 28, 2012

(30) Foreign Application Priority Data
Nov. 30, 2011 (JP) 2011-263133

(51) Int. Cl. G01R 33/48

(52) U.S. Cl. CPC G01R 33/4818
USPC 324/318

(57) ABSTRACT

A magnetic resonance apparatus is provided. The magnetic resonance apparatus is configured to divide k space into a data acquisition region and a data non-acquisition region, and execute a scan including a sequence group in which an imaging sequence is executed a plurality of times, thereby acquiring data disposed in the data acquisition region, wherein data acquired by imaging sequences of the first to i-th times in the imaging sequences of the plurality of times is disposed in the data acquisition region so as to be arranged in a direction away from the data non-acquisition region from a position on a side of the data acquisition region that is adjacent to the data non-acquisition region, and wherein the magnetic resonance apparatus has scan means configured to execute the scan such that a flip angle of an RF pulse of the imaging sequences of the first to i-th times gradually increases.

### CROSS REFERENCE TO RELATED APPLICATIONS

This application claims the benefit of Japanese Patent Application No. 2011-263133 filed Nov. 30, 2011, which is hereby incorporated by reference in its entirety.

### BACKGROUND OF THE INVENTION

The present invention relates to a magnetic resonance apparatus dividing k space into a data acquisition region in which data is acquired and a data non-acquisition region in which data is not acquired, and acquiring data disposed in the data acquisition region.

As a method of realizing higher speed of imaging, a method of collecting only data in a region as a part of k space is known. See, for example, Japanese Unexamined Patent Application Publication No. 2010-042245.

“Partial kz” of partially acquiring data in the kz direction of the k space is also known. However, in the case of acquiring data by the partial kz, a large signal intensity gap tends to occur between a region in which data is not acquired and a region in which data is acquired in the k space, and it may cause artifacts. Therefore, it is demanded to acquire data so that the signal intensity gap becomes as small as possible.

### BRIEF DESCRIPTION OF THE INVENTION

In one aspect, a magnetic resonance apparatus is provided. The magnetic resonance apparatus is configured for dividing k space into a data acquisition region in which data is acquired and a data non-acquisition region in which data is not acquired and executing a scan including a sequence group in which an imaging sequence is executed a plurality of times, thereby acquiring data disposed in the data acquisition region, wherein data acquired by imaging sequences of the first to i-th times in the imaging sequences of the plurality of times is disposed in the data acquisition region so as to be arranged in a direction away from the data non-acquisition region from a position on the side adjacent to the data non-acquisition region in the data acquisition region, and the apparatus has scan means that executes the scan so that a flip angle of an RF pulse of the imaging sequences of the first to i-th times gradually increases.

In another aspect, a magnetic resonance apparatus is provided. The magnetic resonance apparatus is configured for dividing k space into a data acquisition region in which data is acquired and a data non-acquisition region in which data is not acquired and executing a scan including a sequence group in which an imaging sequence is executed a plurality of times, thereby acquiring data disposed in the data acquisition region, wherein the imaging sequences of the plurality of times are divided in a plurality of segments, data acquired by imaging sequences of the first to i-th times in each segment is disposed in the data acquisition region so as to be arranged in a direction away from the data non-acquisition region from a position on the side adjacent to the data non-acquisition region in the data acquisition region, and the apparatus has scan means that executes the scan so that a flip angle of an RF pulse of the imaging sequences of the first to i-th times gradually increases.

In another aspect, a magnetic resonance apparatus is provided. The magnetic resonance apparatus is configured for dividing k space into a data acquisition region in which data is acquired and a data non-acquisition region in which data is not acquired and executing a scan including a sequence group in which an imaging sequence is executed a plurality of times, thereby acquiring data disposed in the data acquisition region, wherein data acquired by imaging sequences of j-th and subsequent times (j>1) in the imaging sequences of the plurality of times is disposed in the data acquisition region so as to be arranged from a position in the data acquisition region toward a position on the side adjacent to the data non-acquisition region in the data acquisition region, and the apparatus has scan means that executes the scan so that a flip angle of an RF pulse of the imaging sequences of the j-th and subsequent times gradually decreases.

In another aspect, a magnetic resonance apparatus is provided. The magnetic resonance apparatus is configured for dividing k space into a data acquisition region in which data is acquired and a data non-acquisition region in which data is not acquired and executing a scan including a sequence group in which an imaging sequence is executed a plurality of times, thereby acquiring data disposed in the data acquisition region, wherein the imaging sequences of the plurality of times are divided in a plurality of segments, data acquired by imaging sequences of the j-th (j>1) and subsequent times in each segment is disposed in the data acquisition region so as to be arranged toward a position on the side adjacent to the data non-acquisition region in the data acquisition region from a position in the data acquisition region, and the apparatus has scan means that executes the scan so that a flip angle of an RF pulse of the imaging sequences of the j-th and subsequent times gradually decreases.

By executing the scan so that the flip angle gradually increases or decreases, the signal intensity gap which occurs between the data acquisition region and the data non-acquisition region in the k space can be made small, and artifact can be reduced.

### BRIEF DESCRIPTION OF THE DRAWINGS

FIG. 1 is a schematic view of a magnetic resonance apparatus of a first mode.

FIG. 2 is an explanatory diagram of a scan executed when an image of a subject 12 is acquired.

FIG. 3 is a diagram schematically showing an imaging region in the subject 12.

FIG. 4 is a diagram showing an imaging sequence using a 3D gradient echo method.

FIG. 5 is an explanatory diagram of a flip angle.

FIG. 6 is a diagram when flip angles of all of imaging sequences A₀ to Aₙ are set to the same angle αₘₐₓ.

FIG. 7 is a graph schematically showing the difference between changes in signal intensity in the kz direction of k space when the flip angles of the imaging sequences A₁ to Aₙ are set as shown in FIG. 5, and changes in signal intensity in the kz direction of the k space when the flip flop angles of the imaging sequences A₁ to Aₙ are set as shown in FIG. 6.

FIG. 8 is a diagram showing a scan in a second mode.

FIG. 9 is a diagram schematically showing an imaging region in a subject.

FIG. 10 is an explanatory diagram of flip angles of a sequence group in a third mode.

FIG. 11 is an explanatory diagram of a scan in a fourth mode.

FIG. 12 is an explanatory diagram of a flip angle in the fourth mode.

FIG. 13 is an explanatory diagram of a flip angle in a fifth mode.

FIG. 14 is a diagram showing simulation results.

FIG. 15 is an explanatory diagram of a flip angle in a sixth mode.

FIG. 16 is a diagram showing a simulation result.

FIG. 17 is a diagram showing a sequence group in a seventh mode.

FIG. 18 is an explanatory diagram of a flip angle in the seventh mode.

FIG. 19 is an explanatory diagram of a scan in an eighth mode.

FIG. 20 is an explanatory diagram of a flip angle in the eighth mode.

FIG. 21 is an explanatory diagram of a scan in a ninth mode.

FIG. 22 is an explanatory diagram of a flip angle in the ninth mode.

### DETAILED DESCRIPTION OF THE INVENTION

Hereinafter, exemplary embodiments will be described. However, the present invention is not limited to the specific embodiments described herein.

(1) First Mode

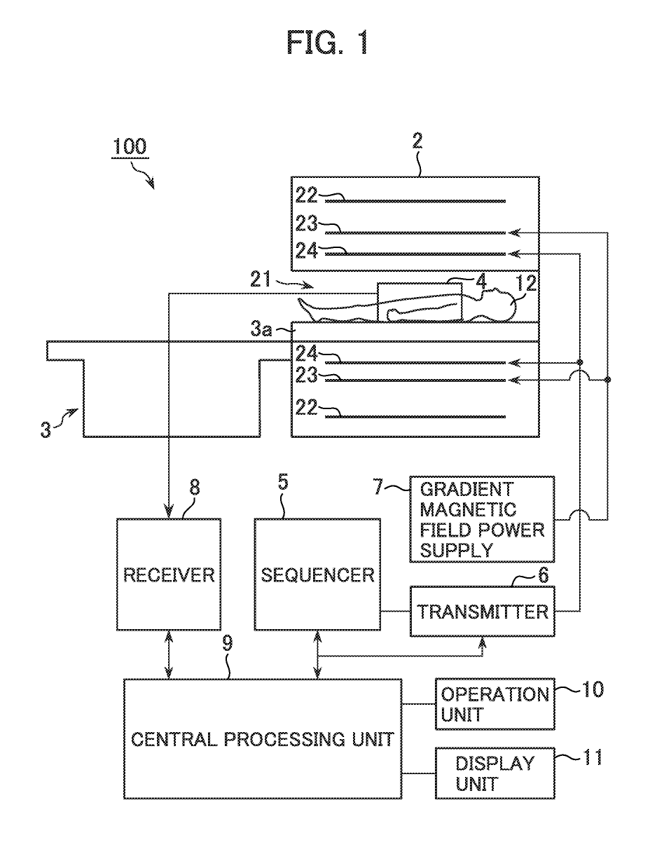

FIG. 1 is a schematic view of a magnetic resonance apparatus of a first mode.

A magnetic resonance apparatus (hereinbelow, called “MR apparatus”) 100 has a magnet 2, a table 3, a reception coil 4, and the like.

The magnet 2 has a bore 21 in which a subject 12 is housed, a superconducting coil 22, a gradient coil 23, a transmission coil 24, and the like. The superconducting coil 22 applies a static magnetic field, the gradient coil 23 applies a gradient field, and the transmission coil 24 transmits RF pulses. In place of the superconducting coil 22, a permanent magnet may be used.

The table 3 has a cradle 3a for supporting the subject 12. By movement of the cradle 3a into the bore 21, the subject 12 is carried in the bore.

The reception coil 4 is attached to the abdominal region of the subject 12.

The MR apparatus 100 also has a sequencer 5, a transmitter 6, a gradient magnetic field power supply 7, a receiver 8, a central processing unit 9, an operation unit 10, and a display unit 11.

Under control of the central processing unit 9, the sequencer 5 sends information for executing a pulse sequence to the transmitter 6 and the gradient magnetic field power supply 7.

The transmitter 6 supplies a signal to the RF coil 24.

The gradient magnetic field power supply 7 supplies a signal to the gradient coil 23.

The receiver 8 processes a magnetic resonance signal received by the reception coil 4 and outputs the processed signal to the central processing unit 9.

The central processing unit 9 controls the operations of the components of the MR apparatus 100 so as to realize various operations of the MR apparatus 100 by transmitting necessary information to the sequencer 5 and the display unit 11, reconstructing an image on the basis of data received from the receiver 8, and performing other things. The central processing unit 9 is constructed by, for example, a computer.

The operation unit 10 is operated by an operator and supplies various information to the central processing unit 9. The display unit 11 displays various information.

The MR apparatus 100 is constructed as described above. A combination of the magnet 2, the sequencer 5, the transmitter 6, the gradient magnetic field power supply 7, and the receiver 8 corresponds to scanning means.

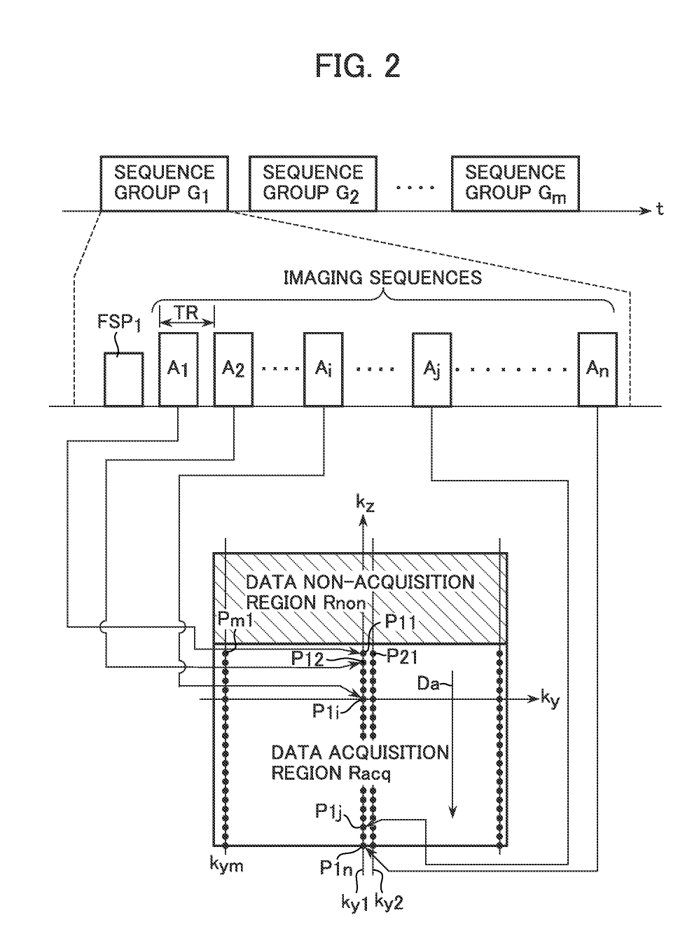

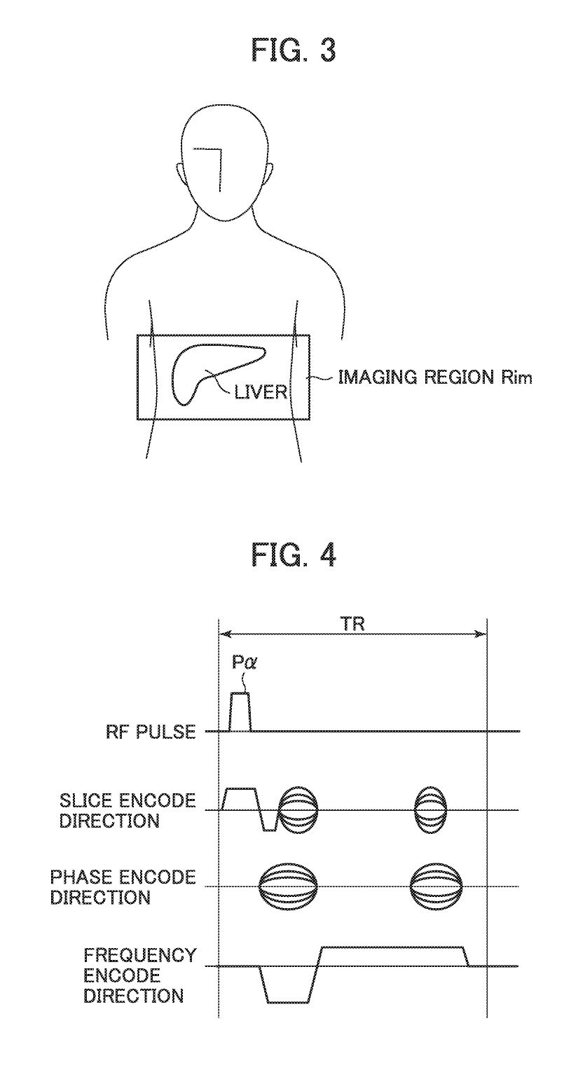

FIG. 2 is an explanatory diagram of a scan executed when an image of the subject 12 is acquired and FIG. 3 is a diagram schematically showing an imaging region in the subject 12.

In a first mode, a region including the liver of the subject 12 is set as an imaging region Rᵢₘ (refer to FIG. 3). To acquire image data of the imaging region Rᵢₘ, as shown in FIG. 3, a scan including sequence groups G₁ to Gₘ is executed.

The sequence group G₁ has a fat suppression pulse FSP₁ and imaging sequences A₁ to Aₙ. Each of the imaging sequences A₁ to Aₙ is a sequence for acquiring image data in the imaging region Rᵢₘ including the liver of the subject 12. The imaging sequences A₁ to Aₙ are executed every repetition time TR.

Each of the other sequence group G₂ to Gₘ has a fat suppression pulse FSP₁ and imaging sequences A₁ to Aₙ like the sequence group G₁. By executing the sequence groups G₁ to Gₘ, data of k space necessary to acquire the image data in the imaging region Rᵢₘ is collected.

In the first mode, the k space is divided into a data non-acquisition region Rₙₒₙ in which data is not acquired and a data acquisition region R_{acq} in which data is acquired. Data acquired by the imaging sequences A₁ to Aₙ in the sequence group G₁ is disposed on a line of ky=ky₁ so as to be arranged in a direction Dₐ away from the data non-acquisition region Rₙₒₙ from a position P₁₁ on the side adjacent to the data non-acquisition region Rₙₒₙ. For example, data acquired by the first to i-th imaging sequences A₁ to Aᵢ is disposed so as to be arranged from the position P₁₁ adjacent to the data non-acquisition region Rₙₒₙ toward a position P₁ᵢ in the data acquisition region R_{acq}. Data acquired by j-th and subsequent (j-th to n-th) imaging sequences Aⱼ to Aₙ is disposed so as to be arranged from a position P₁ⱼ in the data acquisition region R_{acq} toward a position P₁ₙ on the side opposite to the data non-acquisition region Rₙₒₙ.

Similarly, data acquired by the other sequences G₂ to Gₘ is disposed on a line of ky=ky₂ to kyₘ so as to be arranged in a direction Dₐ away from the data non-acquisition region Rₙₒₙ from positions P₂₁ to Pₘ₁ on the side adjacent to the data non-acquisition region Rₙₒₙ.

Next, the imaging sequences A₁ to Aₙ will be described. FIG. 4 shows an imaging sequence using a 3D gradient echo method as an example of the imaging sequences A₁ to Aₙ. In each of the sequence groups G₁ to Gₘ, the imaging sequence shown in FIG. 4 is repeated every repetition time TR. In the first mode, the flip angles of RF pulses P_{α} of the imaging sequences A₁ to Aₙ are not the same values. With respect to the imaging sequences A₁ to Aᵢ, the flip angles of RF pulses P_{α} are set so as to gradually increase. The flip angles of RF pulses P_{α} in the first mode will be described below.

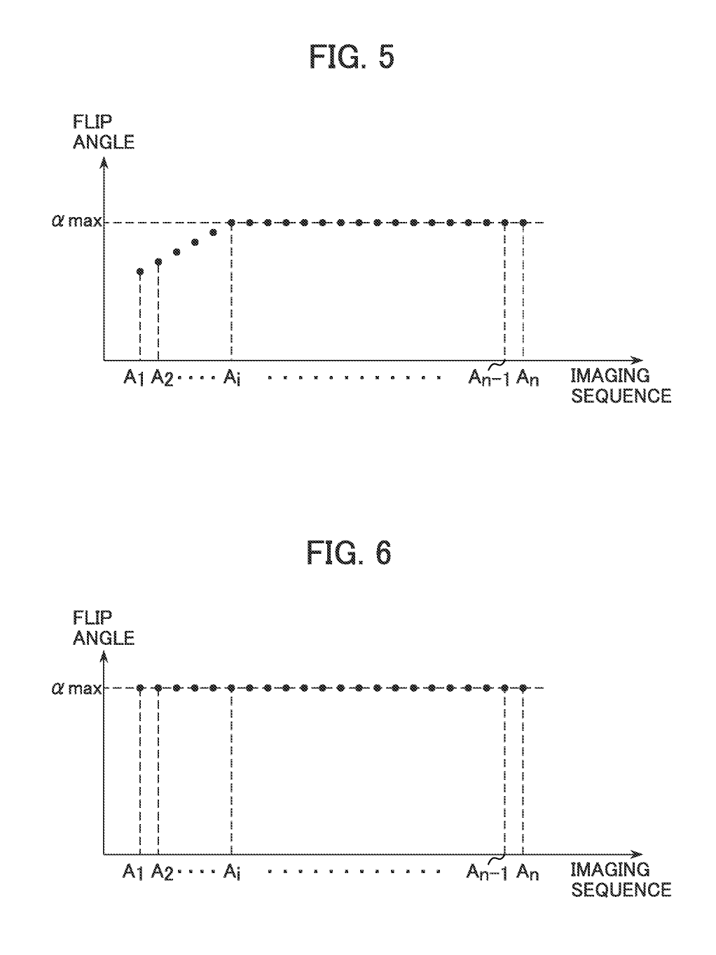

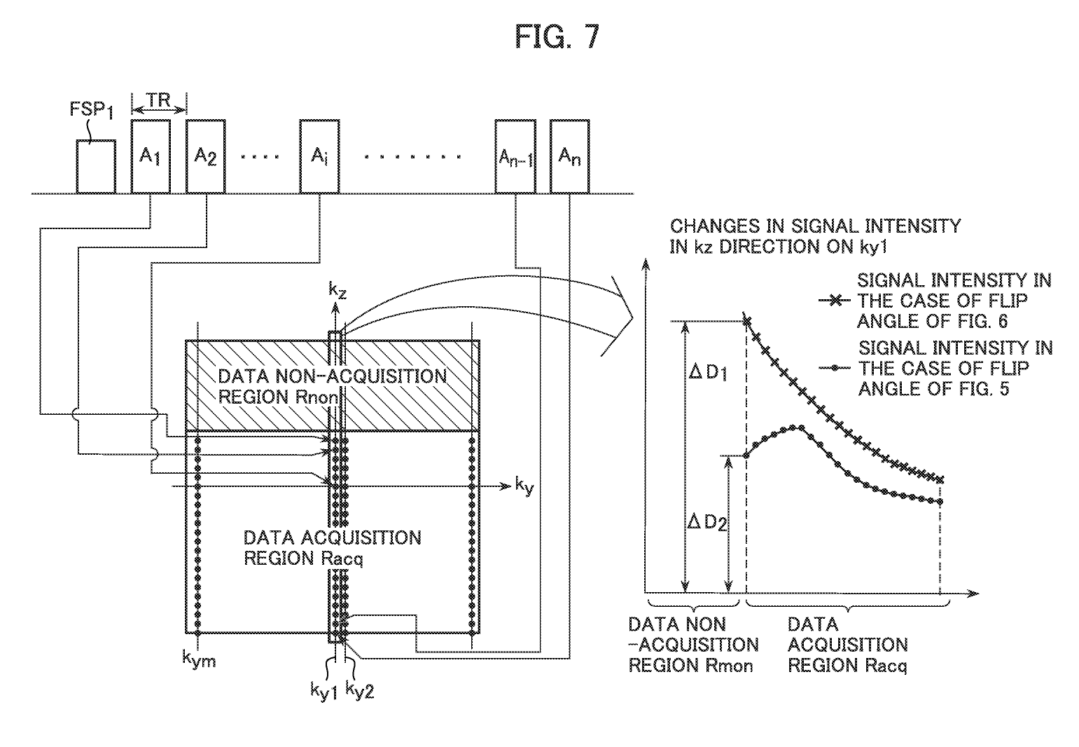

FIG. 5 is an explanatory diagram of the flip angle.

The horizontal axis of a graph of FIG. 5 indicates the imaging sequences A₁ to Aₙ and the vertical axis of the graph shows the flip angles of RF pulses P_{α} of the imaging sequences A₁ to Aₙ.

The RF pulses P_{α} of the imaging sequences Aᵢ to Aₙ executed in the i-th to n-th times are set to the same flip angle αₘₐₓ (for example, αₘₐₓ=30°). However, the flip angles of the RF pulses P_{α} of the imaging sequences A₁ to Aᵢ executed in the first to i-th times gradually increase and reach αₘₐₓ. By setting the flip angle as shown in FIG. 5, there is an effect such that artifact can be reduced as compared with the case of setting the flip angles of all of the imaging sequences A₁ to Aₙ to the same value αₘₐₓ (refer to FIG. 6). Hereinafter, the reason why the effect is obtained will be described with reference to FIG. 7.

FIG. 7 is a graph schematically showing the difference between changes in signal intensity in the kz direction of k space when the flip angles of the imaging sequences A₁ to Aₙ are set as shown in FIG. 5, and changes in signal intensity in the kz direction of the k space when the flip flop angles of the imaging sequences A₁ to Aₙ are set as shown in FIG. 6.

Although FIG. 7 shows changes in the signal intensity in the kz direction when ky=ky₁, changes in the signal intensity in the kz direction when ky=ky₂ to kyₘ are also shown by graphs similar to FIG. 6.

In the case where all of flip angles of all of the imaging sequences A₁ to Aₙ are set to the same value αₘₐₓ (in the case of the flip angle of FIG. 6), the signal intensity of a magnetic resonance signal acquired by the imaging sequence A₁ is the maximum and the signal intensity gradually decreases. Therefore, a large gap ΔD₁ in signal intensity appears between the data non-acquisition region Rₙₒₙ and the data acquisition region R_{acq} in the k space, and it causes artifact.

On the other hand, in the case where the flip angles of the imaging sequences A₁ to Aᵢ are allowed to gradually increase and reach αₘₐₓ (in the case of the flip angle of FIG. 5), the flip angle of the imaging sequence A₁ becomes a value sufficiently smaller than αₘₐₓ. Therefore, a gap ΔD₂ in signal intensity which appears between the data non-acquisition region Rₙₒₙ and the data acquisition region R_{acq} in the k space can be made smaller than ΔD₁, so that artifact can be reduced.

Although the sequence group has the fat suppression pulse FSP₁ in the first mode, in the case where it is unnecessary to suppress fat, the fat suppression pulse FSP₁ may not be provided.

Although the example of sequentially acquiring data in the k space has been described above, if the gap in the k space can be reduced, another acquisition order may be employed.

(2) Second Mode

A second mode is different from the first mode with respect to sequence groups, but the other points are similar to those of FIG. 1. Therefore, in description of the second mode, the sequence groups will be mainly described.

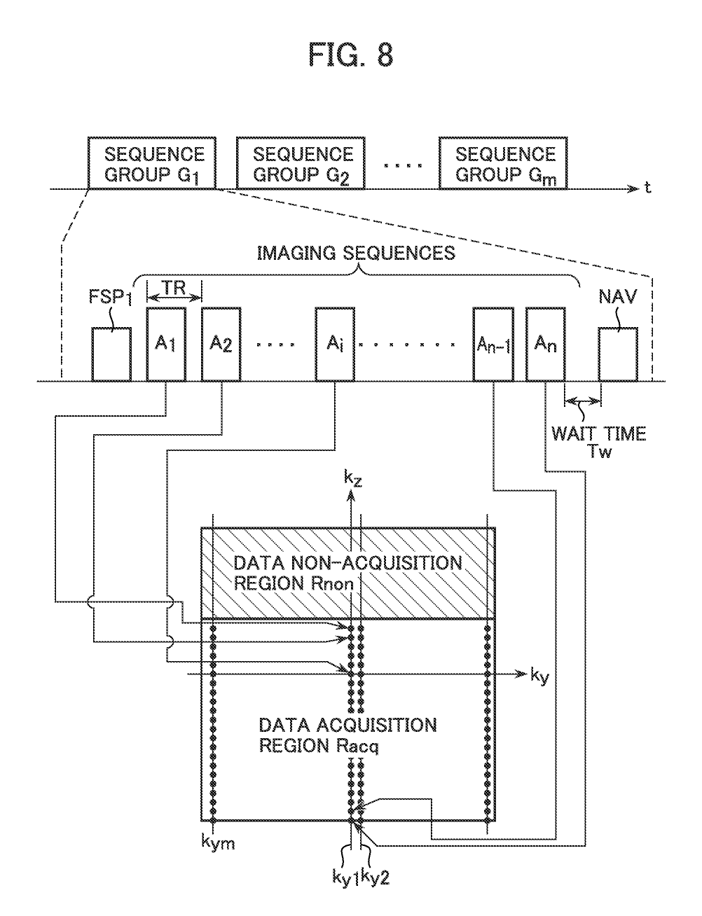

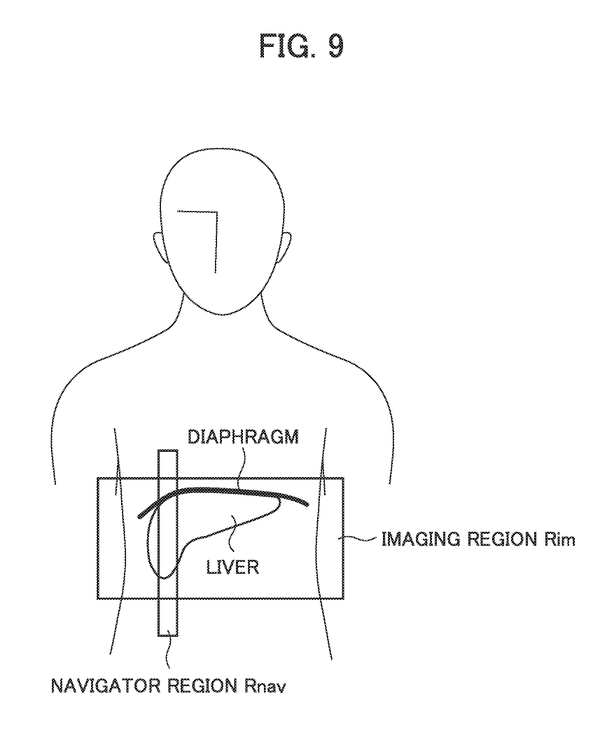

FIG. 8 is a diagram showing a scan in the second mode, and FIG. 9 is a diagram schematically showing an imaging region in a subject.

In the second mode, after the last imaging sequence Aₙ, a navigator sequence NAV is provided. The other points are the same as those of the first mode (refer to FIG. 2). The navigator sequence NAV is a sequence for detecting a respiratory signal of the subject and is, concretely, a sequence for acquiring navigator data indicative of the position of a diaphragm from a navigator region Rₙₐᵥ (refer to FIG. 3) including the diaphragm. By providing the navigator sequence NAV as described above, an image of the subject can be acquired by a respiratory-gated imaging method.

Since the imaging sequences A₁ to Aₙ are included in one sequence group, each time the imaging sequence is executed, an RF pulse is transmitted. Therefore, in the imaging region Rᵢₘ, due to the spin saturation effect, the longitudinal magnetization of spin gradually decreases. After the longitudinal magnetization becomes small, the navigator sequence NAV is executed. However, since the navigator region Rₙₐᵥ excited by the navigator sequence NAV overlaps the imaging region Rᵢₘ, immediately after the last imaging sequence Aₙ is finished, magnetization in the navigator region Rₙₐᵥ is considerably small. Therefore, when the navigator sequence NAV is executed immediately after completion of the imaging sequence Aₙ, a navigator signal deteriorates due to small magnetization in the navigator region Rₙₐᵥ, and precision of detecting the position of the diaphragm may deteriorate.

In the second mode, therefore, wait time T_{W} is provided between the last imaging sequence Aₙ and the navigator sequence NAV. By providing the wait time T_{W}, the magnetization in the navigator region Rₙₐᵥ can be restored. Consequently, deterioration in the navigator signal can be suppressed, and the precision of detecting the position of the diaphragm can be improved. The wait time T_{W} can be set to, for example, about 20 msec. When sufficient detection precision is obtained, the wait time T_{W} may not be provided.

(3) Third Mode

A third mode is different from the third mode with respect to the flip angle of the sequence group but the other points are the same as those of the first mode. Therefore, in description of the third mode, the flip angle of the sequence group will be mainly described.

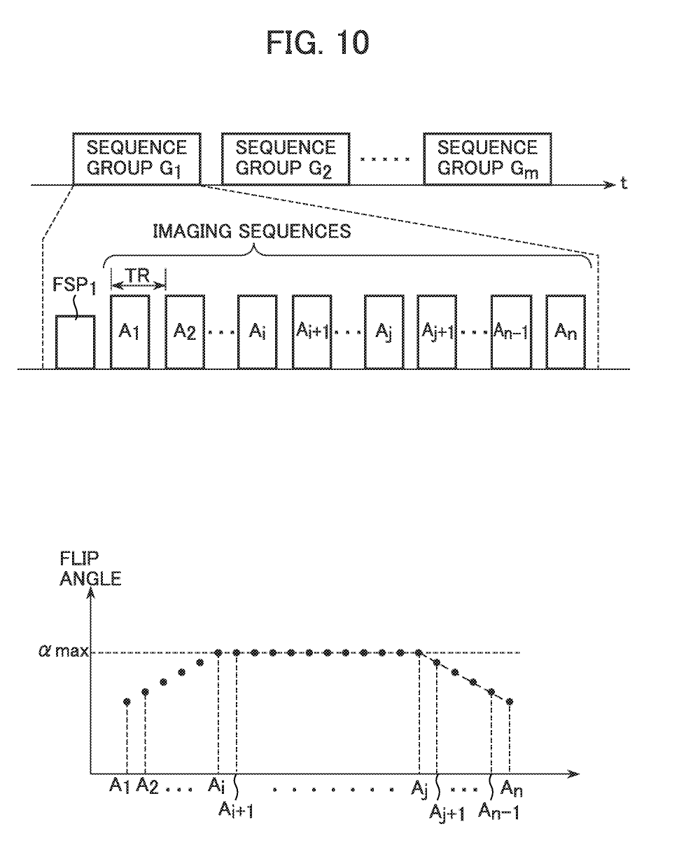

FIG. 10 is an explanatory diagram of flip angles of a sequence group in the third mode.

In the third mode, the flip angle of RF pulses P_{α} of the imaging sequences A₁ to Aₙ executed first time to the i-th time gradually increases and reaches αₘₐₓ. The RF pulse P_{α} of the imaging sequences A₁ to Aₙ executed the i-th time to the j-th time is set to the same flip angle αₘₐₓ (for example, αₘₐₓ=30°). Until now, the third mode is similar to the first mode. In the third mode, however, the flip angle of RF pulses P_{α} of the imaging sequences Aⱼ to Aₙ executed the j-th time and subsequent times (the j-th time to the n-th time) is set so as to gradually decrease from αₘₐₓ. Although the flip angle of the sequence group G₁ has been described with reference to FIG. 10, the flip angles of the other sequence groups G₂ to Gₘ are also expressed by the flip angle shown in FIG. 10.

By gradually increasing the flip angle and, in addition, gradually decreasing the flip angle from the middle, artifact in an image can be further reduced.

Also in the third mode, in a manner similar to the first mode, the order of collecting data in the k space is not limited to the sequential order but the data may be acquired by another acquisition method. Further, in a manner similar to the second mode, the navigator sequence NAV may be provided (refer to FIG. 8). In the case of providing the navigator sequence NAV, by providing the wait time T_{W} between the last imaging sequence Aₙ and the navigator sequence NAV, deterioration in the navigator signal can be suppressed, and the precision of detecting the position of the diaphragm can be improved.

(4) Fourth Mode

A fourth mode is different from the first mode with respect to the sequence groups but the other points are the same as those of the first mode. Therefore, in description of the fourth mode, the sequence groups will be described mainly.

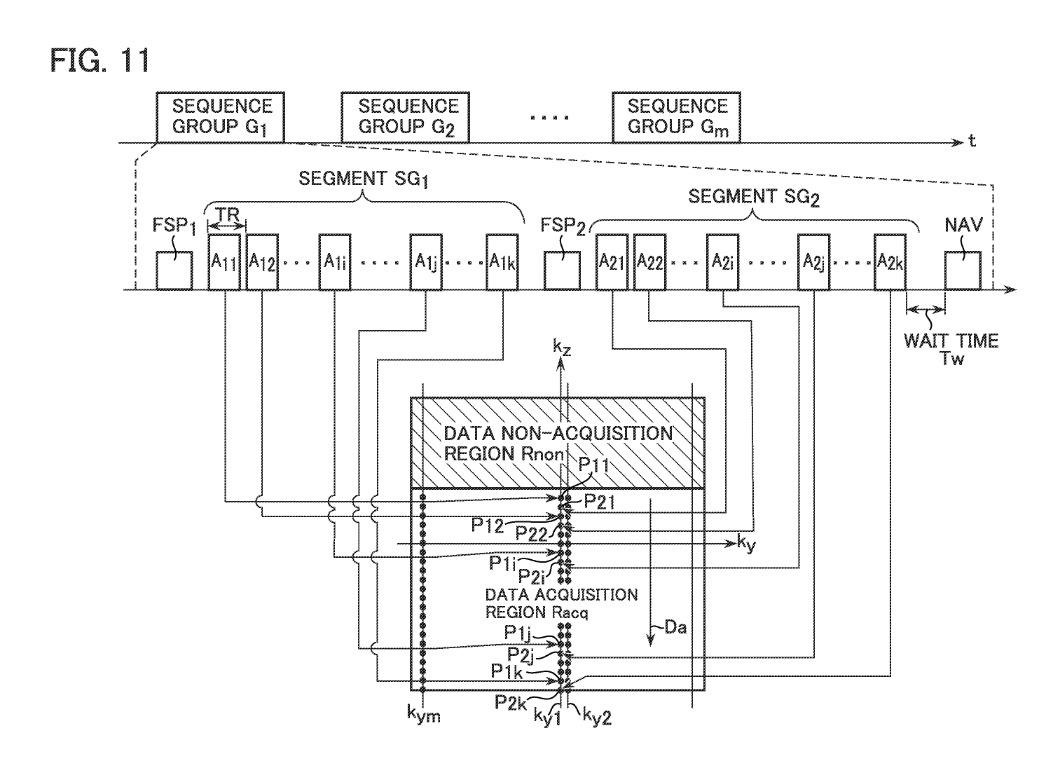

FIG. 11 is an explanatory diagram of a scan in the fourth mode. In the fourth mode, a scan including sequence groups G₁ to is executed.

The sequence group G₁ has two fat suppression pulses FSP₁ and FSP₂, two segments SG₁ and SG₂, and the navigator sequence NAV. The segment SG₁ has imaging sequences A₁₁ to A₁ₖ. The segment SG₂ has imaging sequences A₂₁ to A₂ₖ. The first fat suppression pulses FSP₁ is provided in front of the imaging sequence A₁₁ and the second fat suppression pulse FSP₂ is provided between the imaging sequences A₁ₖ and A₂₁.

Data acquired by the imaging sequences A₁₁ to A₁ₖ in the segment SG₁ is disposed on a line of ky=ky₁ so as to be arranged in a direction Dₐ away from the data non-acquisition region Rₙₒₙ from a position P₁₁ on the side adjacent to the data non-acquisition region Rₙₒₙ. The segment SG₁ acquires data in positions where kz coordinate values are odd numbers on the line of ky=ky₁.

For example, data acquired by the first to i-th imaging sequences A₁₁ to A₁ᵢ is disposed in positions where the kz coordinate values are odd numbers from the position P₁₁ adjacent to the data non-acquisition region toward a position P₁ᵢ in the data acquisition region R_{acq}. Data acquired by j-th and subsequent (j-th to k-th) imaging sequences A₁ⱼ to A₁ₖ is disposed in positions where the kz coordinate values are odd numbers from a position P₁ⱼ in the data acquisition region R_{acq} toward a position P₁ₖ on the side opposite to the data non-acquisition region Rₙₒₙ.

On the other hand, data acquired by the imaging sequences A₂₁ to A₂ₖ in the segment SG₂ is disposed on the line of ky=ky₁ so as to be arranged in the direction Dₐ away from the data non-acquisition region Rₙₒₙ from a position P₂₁ on the side adjacent to the data non-acquisition region Rₙₒₙ. The segment SG₂ acquires data in positions where kz coordinate values are even numbers on the line of ky=ky₁.

For example, data acquired by the first to i-th imaging sequences A₂₁ to A₂ᵢ is disposed in positions where the kz coordinate values are even numbers from the position P₂₁ adjacent to the data non-acquisition region Rₙₒₙ toward a position P₂ᵢ in the data acquisition region R_{acq}. Data acquired by j-th and subsequent (j-th to k-th) imaging sequences A₂ⱼ to A₂ₖ is disposed in positions where the kz coordinate values are even numbers from a position P₂ⱼ in the data acquisition region R_{acq} toward a position P₂ₖ on the side opposite to the data non-acquisition region Rₙₒₙ.

Like the sequence group G₁, each of the other sequence groups G₂ to Gₘ has two fat suppression pulses FSP₁ and FSP₂, two segments SG₁ and SG₂, and the navigator sequence NAV and acquires data on the line of ky=ky₂ to kyₘ.

Next, the flip angle of the imaging sequence in the fourth mode will be described.

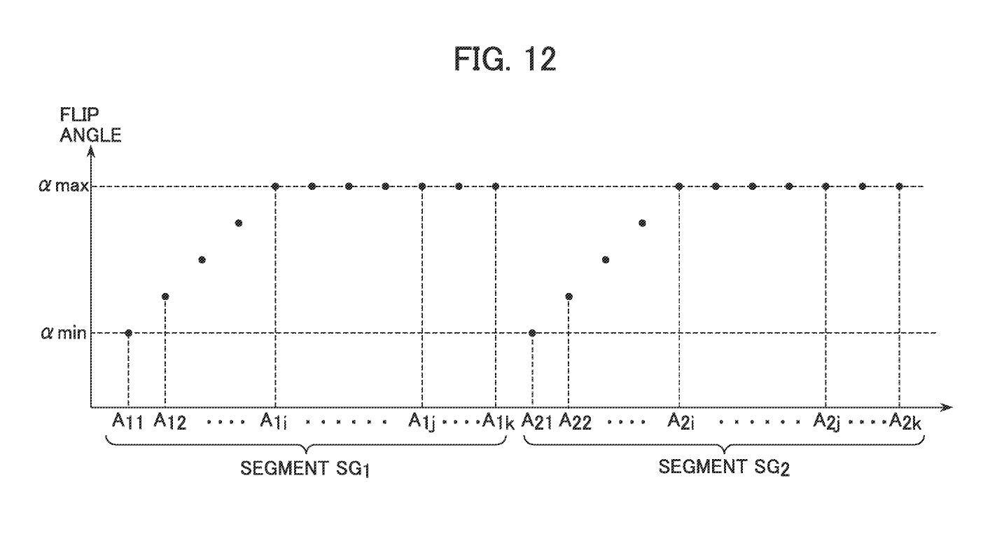

FIG. 12 is an explanatory diagram of the flip angle.

The horizontal axis of a graph of FIG. 12 indicates the imaging sequences A₁ₗ to A₁ₖ of the first segment SG₁ and the imaging sequences A₂₁ to A₂ₖ of the second segment SG₂. The vertical axis of the graph shows the flip angles of RF pulses P_{α} of the imaging sequences.

In the first segment SG₁, the flip angles of the RF pulses P_{α} of the imaging sequences A₁₁ to A₁ᵢ executed in the first to i-th times are set so as to gradually increase from αₘᵢₙ and reach αₘₐₓ. The RF pulses P_{α} of the imaging sequences A₁ᵢ to A₁ₖ executed in the i-th time to the k-th time are set to the same flip angle αₘₐₓ.

Also in the second segment SG₂, in a manner similar to the first segment SG₁, the flip angles of the RF pulses P_{α} of the imaging sequences A₂₁ to A₂ᵢ executed in the first to i-th times are set so as to gradually increase from αₘᵢₙ and reach Aₘₐₓ. The RF pulses P_{α} of the imaging sequences A₂ᵢ to A₂ₖ executed in the i-th time to the k-th time are set to the same flip angle αₘₐₓ.

By setting the flip angles in the first and second segments SG₁ and SG₂ as shown in FIG. 12, the difference between the signal intensity obtained in the segment SG₁ and the signal intensity obtained in the segment SG₂ can be made smaller, so that artifact can be further reduced.

In the fourth mode, one sequence group is provided with the two fat suppression pulses FSP₁ and FSP₂. By providing two fat suppression pulses in such a manner, even if the fat suppression effect of the first fat suppression pulse FSP₁ is lost in the middle, by the fat suppression effect of the second fat suppression pulse FSP₂, the fat suppression effect can be maintained while one sequence group is executed.

In the fourth mode, data in the positions where the kz coordinate values are odd numbers is acquired by the first segment SG₁ and, subsequently, data in the positions where the kz coordinate values become even numbers is acquired by the second segment SG₂. Alternatively, the data may be acquired by another acquiring method (for example, data in the positions where the Kz coordinate values are even numbers is acquired first and, subsequently, data in the positions where the kz coordinate values become odd numbers is acquired). Further, although the navigator sequence NAV is provided in the fourth mode, in the case where it is unnecessary to perform imaging by the respiratory-gated imaging method, the navigator sequence NAV may not be provided.

In the first segment SG₁, the flip angles of the first to i-th imaging sequences A₁₁ to A₁ᵢ are set so as to gradually increase. In the following segment SG₂, the flip angles of the first to i-th imaging sequences A₂₁ to A₂ᵢ are set so as to gradually increase. The values of i in the segments SG₁ and SG₂ can be set to the same value. For example, i is set to 5 (i=5) in the first segment SG₁ and i can be set to 5 (i=5) also in the following segment SG₂. In this case, in the segment SG₁, the flip angles of the first to fifth imaging sequences A₁₁ to A₁₅ gradually increase. In the following segment SG₂, the flip angles of the first to fifth imaging sequences A₂₁ to A₂₅ gradually increase.

On the other hand, the values of i in the segments SG₁ and SG₂ may be set to different values. For example, i is set to 5 (i=5) in the first segment SG₁ and i can be set to 6 (i=6) in the following segment SG₂. In this case, in the segment SG₁, the flip angles of the first to fifth imaging sequences A₁₁ to A₁₅ gradually increase. In the following segment SG₂, the flip angles of the first to sixth imaging sequences A₂₁ to A₂₆ gradually increase.

(5) Fifth Mode

A fifth mode is different from the fourth mode with respect to the flip angle of the sequence group, but the other points are the same as those of the fourth mode. Therefore, in description of the fifth mode, the flip angle of the sequence group will be mainly described.

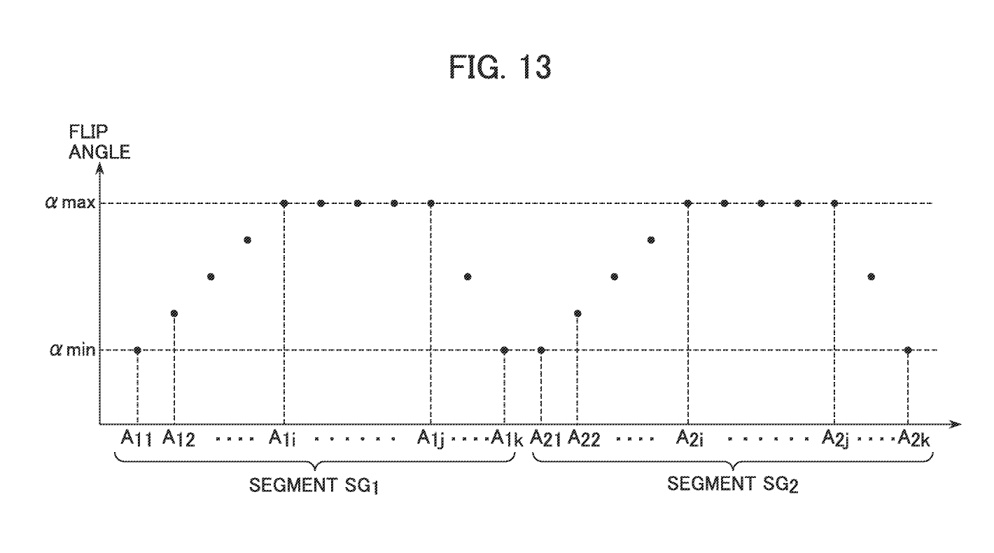

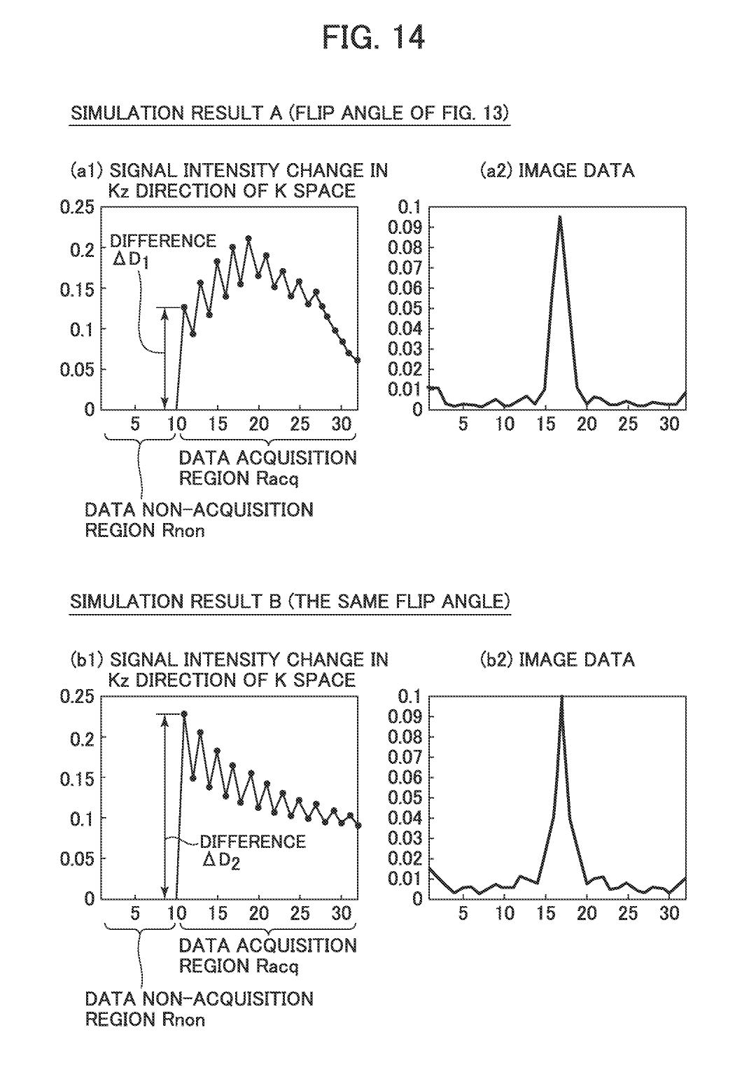

FIG. 13 is an explanatory diagram of the flip angle.

In the first segment SG₁, the flip angles of the RF pulses P_{α} of the imaging sequences A₁₁ to A₁ᵢ executed in the first to i-th times are set so as to gradually increase from αₘᵢₙ and reach αₘₐₓ. The RF pulses P_{α} of the imaging sequences A₁ᵢ to A₁ⱼ executed in the i-th time to the j-th time are set to the same flip angle αₘₐₓ. Until now, the fifth mode is the same as the fourth mode. In the fifth mode, however, the flip angles of the RF pulses P_{α} of the imaging sequences A₁ⱼ to A₁ₖ executed in the j-th and subsequent times (the j-th time to the k-th time) are set so as to gradually decrease from αₘₐₓ.

Also in the second segment SG₂, the flip angles increase and decrease in a manner similar to the first segment SG₁.

In the fifth mode, the flip angle of the RF pulse P_{α} is gradually increased to reach αₘₐₓ, after that, maintained at αₘₐₓ, and gradually decreased from the middle. As described above, by gradually increasing the flip angle of the RF pulse Pα and, in addition, gradually decreasing the flip angle from the middle, artifact can be further reduced. To verify that artifact can be further reduced, a simulation of a point spread function expressing spread of a point function when the point function is received by using a pulse sequence having the flip angle of FIG. 13 was performed. Simulation parameters are as follows.

(1) the maximum value αₘₐₓ of flip angle=30°

(2) the minimum value αₘᵢₙ of flip angle=15®

(3) the number of imaging sequences A₁ₗ to A₁ₖ in the segment SG₁=11

(4) the number of imaging sequences A₂₁ to A₂ₖ in the segment SG₂=11

FIG. 14 is a diagram showing simulation results.

FIG. 14 shows two simulation results A and B. The simulation result A is a simulation result when the flip angles of the imaging sequences A₁₁ to A₂ₖ are set to the flip angles shown in FIG. 13. On the other hand, the simulation result B is provided to be compared with the simulation result A and is a simulation result when the flip angles of the imaging sequences A₁₁ to A₂ₖ are set to the same value Aₘₐₓ=30°.

Graphs (a1) and (b1) on the left side of the simulation results A and B are diagrams showing signal intensity changes in the kz direction of the k space, and graphs (a2) and (b2) on the right side are diagrams showing image data.

When the signal intensity changes in the graph (a1) and those in the graph (b1) are compared, the gap ΔD₁ of the signal intensity in the graph (a1) is smaller than the gap ΔD₂ of the signal intensity in the graph (b1). When the image data in the graph (a2) and that in the graph (b2) are compared, the data values on both sides of the peak in the image data of the graph (a2) are suppressed more than those in the image data of the graph (b2). It is therefore understood that, by setting the flip angles of the imaging sequences A₁₁ to A₂ₖ to the flip angles shown in FIG. 13, artifact can be reduced.

In the fifth mode, in a manner similar to the fourth mode, in the first segment SG₁, the flip angles of the imaging sequences A₁₁ to A₁, in the first to i-th times are set so as to gradually increase. In the following segment SG₂, the flip angles of the imaging sequences A₂₁ to A₂₁ in the first to i-th times are set so as to gradually increase. Also in the fifth mode, the values of “i” in the segments SG₁ and SG₂ may be the same value or different values.

In the fifth mode, in the first segment SG₁, the flip angles of the imaging sequences A₁ⱼ to A₁ₖ in the j-th and subsequent times (the j-th time to the k-th time) are set so as to gradually decrease. In the following segment SG₂, the flip angles of the imaging sequences A₂ⱼ to A₂ₖ in the j-th and subsequent times (the j-th time to the k-th time) are set so as to gradually decrease. The value of “j” in the first segment SG₁ can be set to the same value as the value of “j” in the next segment SG₂. For example, j is set to 9 (i=9) in the first segment SG₁ and j can be set to 9 (i=9) also in the following segment SG₂. In this case, in the segment SG₁, the flip angles of the ninth to k-th imaging sequences A₁₉ to A₁ₖ gradually decrease. Also in the following segment SG₂, the flip angles of the ninth to k-th imaging sequences A₂₉ to A₂ₖ gradually decrease.

On the other hand, the values of j in the segments SG₁ and SG₂ may be set to different values. For example, j is set to 9 (j=9) in the first segment SG₁ and j can be set to 8 (j=8) in the following segment SG₂. In this case, in the segment SG₁, the flip angles of the ninth to k-th imaging sequences A₁₉ to A₁ₖ gradually decrease. In the following segment SG₂, the flip angles of the eighth to k-th imaging sequences A₂₈ to A₂ₖ gradually decrease.

(6) Sixth Mode

A sixth mode is different from the fifth mode with respect to the flip angle of the sequence group, but the other points are the same as those of the fifth mode. Therefore, in description of the sixth mode, the flip angle of the sequence group will be mainly described.

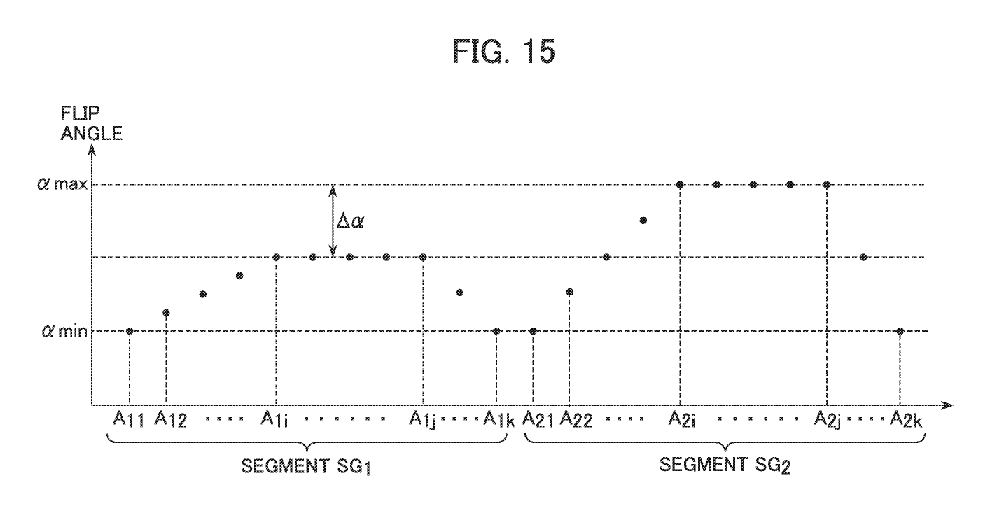

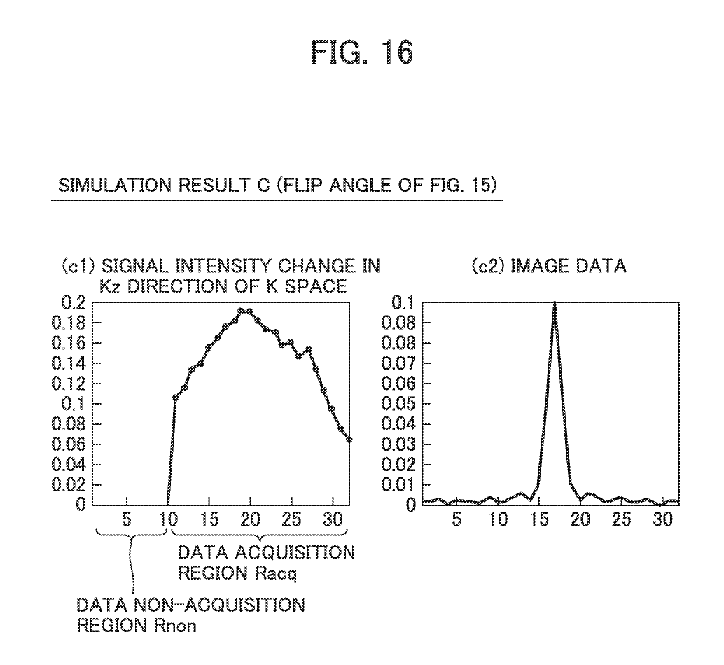

FIG. 15 is an explanatory diagram of the flip angle.

In the sixth mode, the flip angle αmax′ of the imaging sequences A₁₁ to A₁ⱼ in the segment SG₁ is set to be smaller than the flip angle αₘₐₓ of the imaging sequences A₂ᵢ to A₂ⱼ in the segment SG₂ only by Δα.

By making the flip angle small, the gap between the signal intensities which are neighboring in the kz direction can be made smaller. To verify that, a simulation when the point function is received by using a pulse sequence having the flip angle shown in FIG. 15 was performed. A simulation parameter is αₘₐₓ′=25° and the other parameters are the same as those in the fifth mode.

FIG. 16 is a diagram showing a simulation result.

FIG. 16 shows a simulation result C when the flip angles of the imaging sequences A₁₁ to A₂ₖ are set to the flip angles shown in FIG. 15. The graph (c1) on the left side of the simulation result C is a diagram showing signal intensity changes in the kz direction of the k space, and the graph (c2) on the right side is a diagram showing image data.

When the signal intensity changes in the graph (c1) in FIG. 16 and those in the graph (a1) in FIG. 14 are compared, the gap of the signal intensities adjacent in the kz direction in the graph (c1) in FIG. 16 is smaller than that in the graph (a1) in FIG. 14. When the image data in the graph (c2) in FIG. 16 and that in the graph (a2) in FIG. 14 are compared, ghost at an end of FOV in the image data of the graph (c2) in FIG. 16 is suppressed more than that in the image data of the graph (a2) in FIG. 14. It is therefore understood that, by setting the flip angles of the imaging sequences A₁₁ to A₁ₖ to the flip angles shown in FIG. 15, artifact can be further reduced.

(7) Seventh Mode

In the fourth to sixth modes, examples that one sequence group has two segments SG1 and SG2 have been described. In a seventh mode, the case where the number of segments is generalized and one sequence group includes z segments will be described.

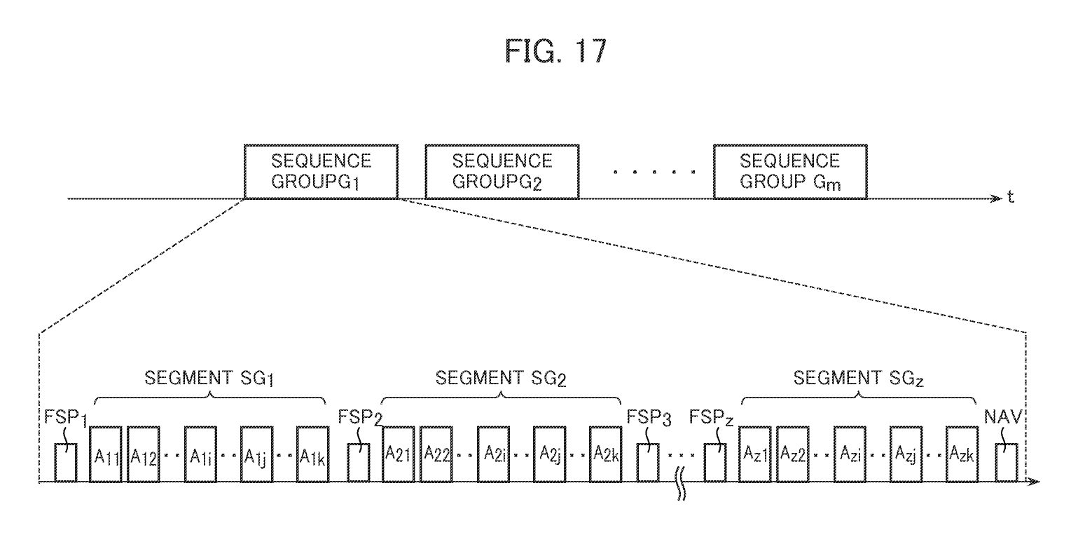

FIG. 17 is a diagram showing a sequence group in the seventh mode.

In the seventh mode, one sequence group has z pieces of fat suppression pulses FSP₁ to FSP_{z}, z pieces of segments SG₁ to SG_{z}, and the navigator sequence NAV.

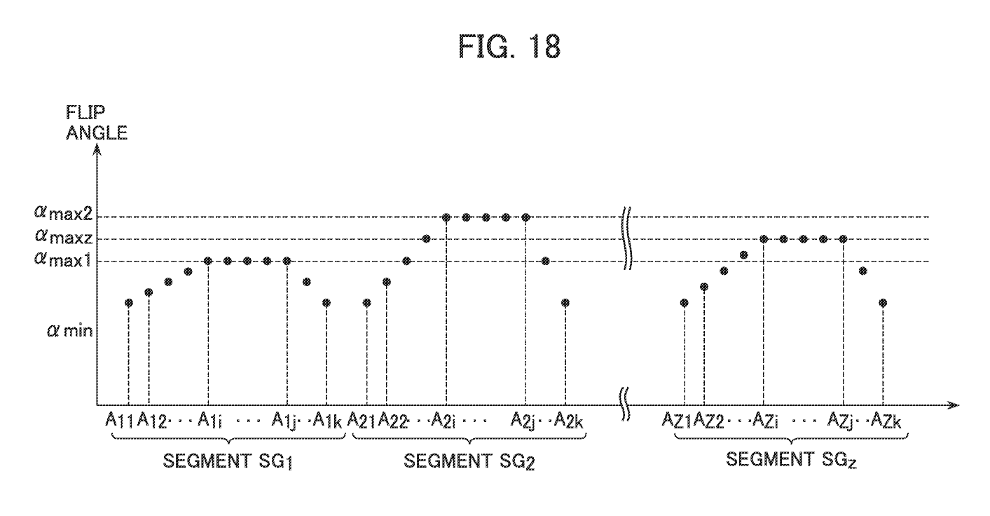

FIG. 18 is a diagram showing the flip angle in the seventh mode.

The flip angles in the segments SG₁ to SG_{z} are set so that the flip angles of the first to i-th imaging sequences gradually increase and the flip angles of the imaging sequences of the j-th and subsequent times (the j-th time to the k-th time) gradually decrease. In the seventh mode, the maximum values of the flip angles of three or more segments in the segments SG₁ to SG_{z} are set to be different from one another. FIG. 18 shows an example that maximum values αₘₐₓ₁, αₘₐₓ₂, and α_{maxz} of the flip angles in the segments SG₁, SG₂, and SG_{z} are set to be different from one another. By setting the maximum values of the flip angles to different values as described above, the gap in the signal intensities adjacent to each other in the kz direction can be further made smaller, so that artifact can be further reduced.

Although each of the segments SG₁ to SG_{z} includes k pieces of imaging sequences, the values of k in the segments SG₁ to SG_{z} may be the same value or different values.

(8) Eighth Mode

In an eighth mode, the case of acquiring data in an acquisition order different from those in the first to seventh modes will be described.

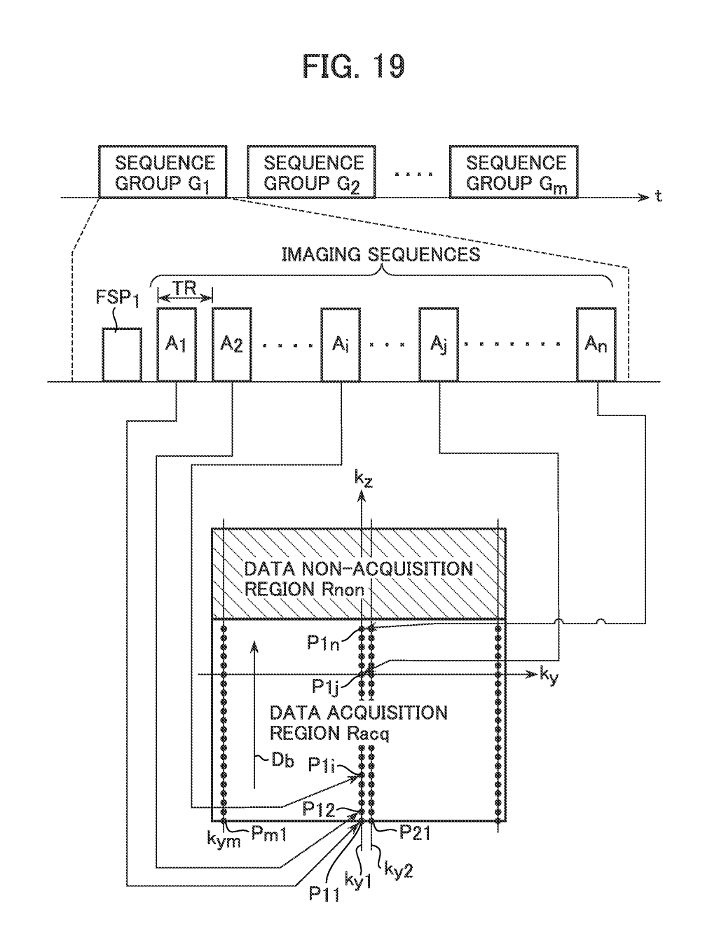

FIG. 19 is an explanatory diagram of a scan in an eighth mode.

In the eighth mode, a scan including sequence groups G₁ to Gₘ is executed.

The sequence group G₁ has the fat suppression pulse FSP₁ and imaging sequences A₁ to Aₙ. Like the sequence group G₁, each of the other sequence groups G₂ to Gₙ has the fat suppression pulse FSP₁ and the imaging sequences A₁ to Aₙ.

The k space is divided into the data non-acquisition region Rₙₒₙ in which data is not acquired and the data acquisition region R_{acq} in which data is acquired. Data acquired by the imaging sequences A₁ to Aₙ in the sequence group G₁ is disposed on a line of ky=ky₁ so as to be arranged in a direction D_{b} toward the data non-acquisition region Rₙₒₙ from a position P₁₁ on the side opposite to the data non-acquisition region Rₙₒₙ. For example, data acquired by the first to i-th imaging sequences A₁ to Aᵢ is disposed so as to be arranged from the position P₁ᵢ on the side opposite to the data non-acquisition region Rₙₒₙ toward the position P₁, in the data acquisition region R_{acq}. Data acquired by j-th and subsequent (j-th to n-th) imaging sequences A₁ to Aₙ is disposed so as to be arranged from the position P₁ⱼ in the data acquisition region R_{acq} toward the position P₁ₙ on the side adjacent to the data non-acquisition region Rₙₒₙ.

Similarly, data acquired by the other sequences G₂ to Gₘ is disposed on a line of ky=ky₂ to kyₘ so as to be arranged in the direction D_{b} toward the data non-acquisition region Rₙₒₙ from positions P₂₁ to Pₘ₁ on the side opposite to the data non-acquisition region Rₙₒₙ.

Next, the flip angle of the imaging sequence in the eighth mode will be described.

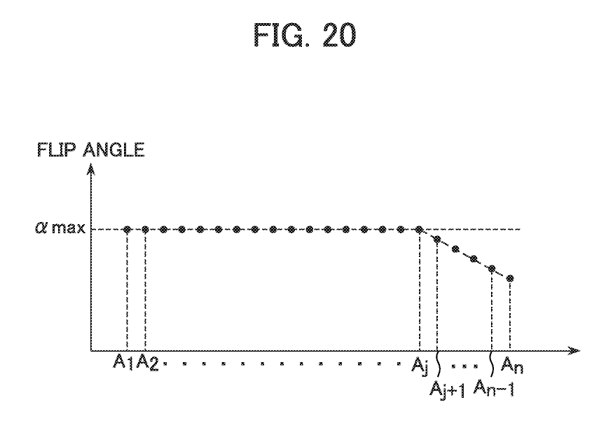

FIG. 20 is an explanatory diagram of the flip angle.

In the eighth mode, the RF pulses P_{α} of the first to i-th imaging sequences A₁ to Aⱼ are set to the same flip angle αₘₐₓ (for example, αₘₐₓ=30°. However, the flip angles of the RF pulses P_{α} of the j-th and subsequent (j-th to n-th) imaging sequences Aⱼ to Aₙ are set so as to be gradually decreased from αₘₐₓ.

By gradually decreasing the flip angle from the middle as shown in FIG. 20, the gap of the signal intensity between the data acquisition region R_{acq} and the data non-acquisition region Rₙₒₙ can be decreased.

Although the sequence group has the fat suppression pulse FSP₁, in the case where it is unnecessary to suppress fat, the fat suppression pulse FSP₁ may not be provided. In the case of performing imaging by the respiratory-gated imaging method, it is sufficient to provide the navigator sequence NAV.

Although the flip angle is set as shown in FIG. 20 in the eighth mode, it may be set as shown in FIG. 10. By the flip angle of FIG. 10, artifact can be further reduced.

(9) Ninth Mode

In a ninth mode, the case where a sequence group is divided in two segments will be described.

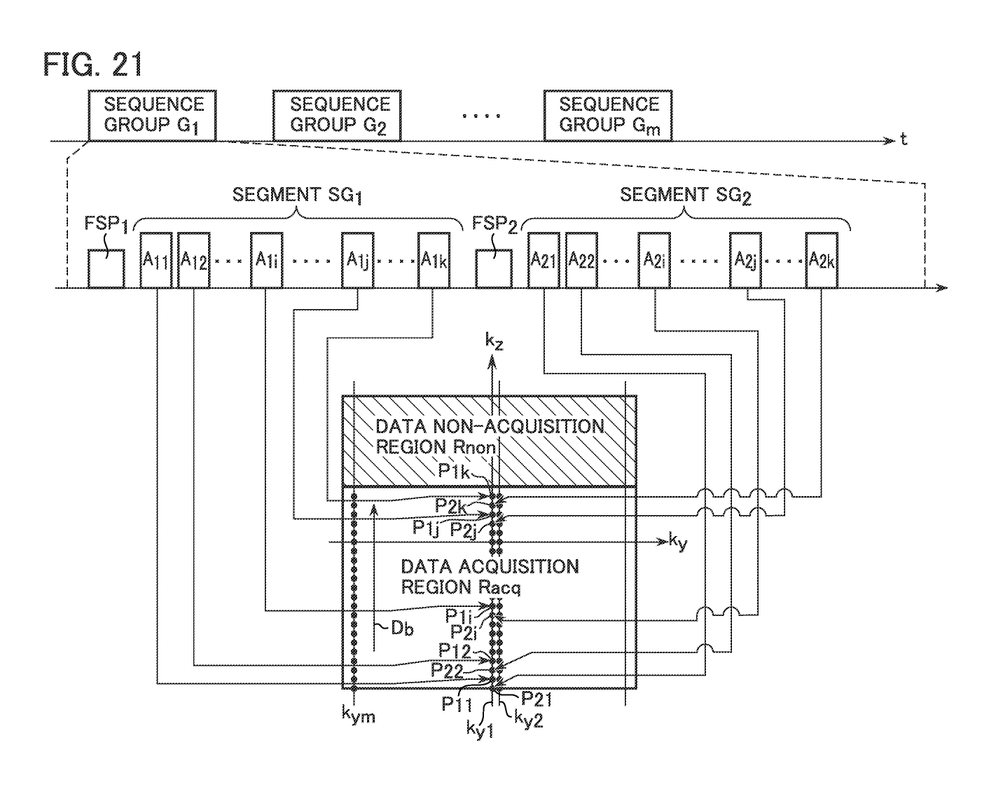

FIG. 21 is an explanatory diagram of a scan in the ninth mode.

In the ninth mode, a scan including the sequence groups G₁ to Gₘ is executed.

The sequence group G₁ has two fat suppression pulses FSP₁ and FSP₂, two segments SG₁ and SG₂, and the navigator sequence NAV. The segment SG₁ has imaging sequences A₁₁ to A₁ₖ, and the segment SG₂ has imaging sequences A₂₁ to A₂ₖ. The first fat suppression pulses FSP₁ is provided in front of the imaging sequence A₁₁ and the second fat suppression pulse FSP₂ is provided between the imaging sequences A₁ₖ and A₂₁.

Data acquired by the imaging sequences A₁₁ to A₁ₖ in the segment SG₁ is disposed on a line of ky=ky₁ so as to be arranged in a direction D_{b} toward the data non-acquisition region Rₙₒₙ from a position P₁₁ on the side opposite to the data non-acquisition region Rₙₒₙ. The segment SG₁ acquires data in positions where kz coordinate values are odd numbers on the line of ky=ky₁.

For example, data acquired by the first to i-th imaging sequences A₁₁ to A₁ᵢ is disposed in positions where the kz coordinate values are odd numbers from the position P₁ᵢ on the side opposite to the data non-acquisition region Rₙₒₙ toward a position P₁ᵢ in the data acquisition region R_{acq}. Data acquired by j-th and subsequent (j-th to k-th) imaging sequences A₁ⱼ to A₁ₖ is disposed in positions where the kz coordinate values are odd numbers from a position P₁ⱼ in the data acquisition region R_{acq} toward a position P₁ₖ on the side adjacent to the data non-acquisition region Rₙₒₙ.

On the other hand, data acquired by the imaging sequences A₂₁ to A₂ₖ in the segment SG₂ is disposed on the line of ky=ky₁ so as to be arranged in the direction D_{b} toward the data non-acquisition region Rₙₒₙ from the position P₂₁ on the side opposite to the data non-acquisition region Rₙₒₙ. The segment SG₂ acquires data in positions where kz coordinate values are even numbers on the line of ky=ky₁.

For example, data acquired by the first to i-th imaging sequences A₂₁ to A₂ᵢ is disposed in positions where the kz coordinate values are even numbers from the position P₂₁ on the side opposite to the data non-acquisition region Rₙₒₙ toward a position P₂, in the data acquisition region R_{acq}. Data acquired by j-th and subsequent (j-th to k-th) imaging sequences A₂ⱼ to A₂ₖ is disposed in positions where the kz coordinate values are even numbers from a position P₂ⱼ in the data acquisition region R_{acq} toward a position P₂ₖ on the side adjacent to the data non-acquisition region Rₙₒₙ.

Like the sequence group G₁, each of the other sequence groups G₂ to Gₘ has two fat suppression pulses FSP₁ and FSP₂, two segments SG₁ and SG₂, and the navigator sequence NAV and acquires data on the line of ky=ky₂ to kyₘ.

Next, the flip angle of the imaging sequence in the ninth mode will be described.

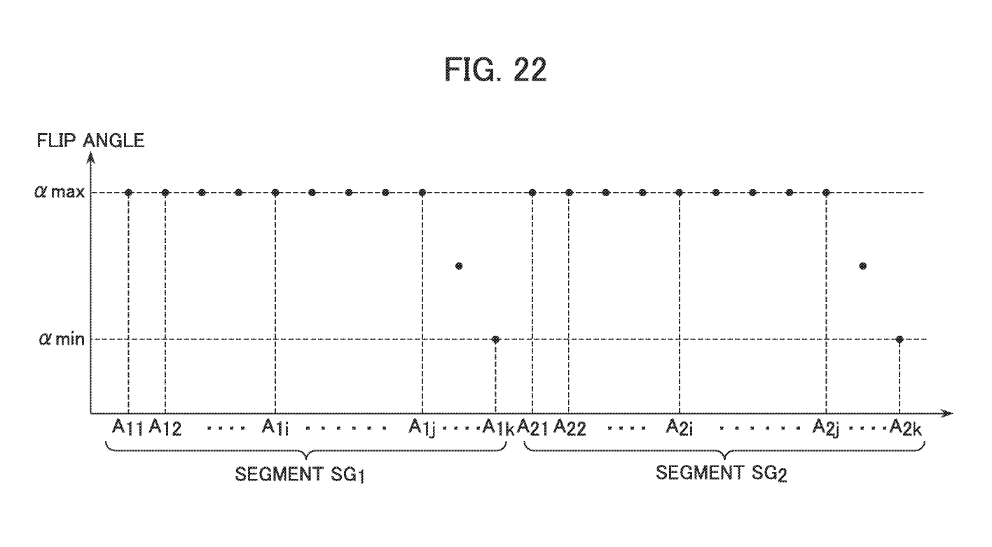

FIG. 22 is an explanatory diagram of the flip angle.

The horizontal axis of a graph of FIG. 22 indicates the imaging sequences A₁₁ to A₁ₖ of the first segment SG₁ and the imaging sequences A₂₁ to A₂ₖ of the second segment SG₂. The vertical axis of the graph shows the flip angles of RF pulses P_{α} of the imaging sequences.

In the first segment SG₁, the flip angles of the RF pulses P_{α} of the imaging sequences A₁₁ to A₁ⱼ of the first to j-th times are set to the same flip angle αₘₐₓ. The RF pulses P_{α} of the imaging sequences A₁ⱼ to A₁ₖ of the j-th and subsequent times are set so as to gradually decrease from αₘₐₓ.

Also in the second segment SG₂, in a manner similar to the first segment SG₁, the flip angles of the RF pulses P_{α} of the imaging sequences A₂₁ to A₂ⱼ of the first to j-th times are set to the same flip angle αₘₐₓ. The RF pulses P_{α} of the imaging sequences A₁ⱼ to A₁ₖ of the j-th and subsequent times are set so as to gradually decrease from αₘₐₓ.

By setting the flip angles in the first and second segments SG₁ and SG₂ as shown in FIG. 22, the difference between the signal intensity obtained in the segment SG₁ and the signal intensity obtained in the segment SG₂ can be made smaller, so that artifact can be further reduced.

Although the navigator sequence NAV is provided in the ninth mode, in the case where it is unnecessary to perform imaging by the respiratory-gated imaging method, the navigator sequence NAV may not be provided.

Although the flip angles are set as shown in FIG. 22 in the ninth mode, they may be set as shown in FIG. 13. By the flip angles of FIG. 13, artifact can be further reduced.

Further, one sequence group may be divided in z pieces of the segments SG₁ to SG_{z} as shown in FIG. 17, and the flip angles may be set as shown in FIG. 18.

1. A magnetic resonance apparatus configured to:
divide k space into a data acquisition region in which data is acquired and a data non-acquisition region in which data is not acquired; and
execute a scan including a sequence group in which an imaging sequence is executed a plurality of times, thereby acquiring data disposed in the data acquisition region, wherein data acquired by imaging sequences of the first to i-th times in the imaging sequences of the plurality of times is disposed in the data acquisition region so as to be arranged in a direction away from the data non-acquisition region from a position on a side of the data acquisition region that is adjacent to the data non-acquisition region, and wherein the magnetic resonance apparatus has scan means configured to execute the scan such that a flip angle of an RF pulse of the imaging sequences of the first to i-th times gradually increases.

2. The magnetic resonance apparatus according to claim 1, wherein the k space has a line crossing the data acquisition region and the data non-acquisition region, and wherein data acquired by the imaging sequences of the first to i-th times is disposed on the line.

3. The magnetic resonance apparatus according to claim 2, wherein data acquired by the imaging sequences of the j-th and subsequent times (where j>i) in the imaging sequences of the plurality of times is disposed on the line so as to be arranged from a first position in the data acquisition region toward a second position on a side of the data acquisition region opposite to the data non-acquisition region, and wherein the scan means is configured to execute the scan such that the flip angle of the RF pulse of the imaging sequences of the j-th and subsequent times gradually decreases.

4. The magnetic resonance apparatus according to claim 1, wherein the sequence group has a navigator sequence for detecting a respiratory signal of a subject.

5. The magnetic resonance apparatus according to claim 4, wherein the navigator sequence is executed after a wait time which is provided after execution of the imaging sequences of the plurality of times.

6. A magnetic resonance apparatus configured to:
divide k space into a data acquisition region in which data is acquired and a data non-acquisition region in which data is not acquired; and
execute a scan including a sequence group in which an imaging sequence is executed a plurality of times, thereby acquiring data disposed in the data acquisition region, wherein the imaging sequences of the plurality of times are divided in a plurality of segments, wherein data acquired by imaging sequences of the first to i-th times in each segment is disposed in the data acquisition region so as to be arranged in a direction away from the data non-acquisition region from a position on a side of the data acquisition region adjacent to the data non-acquisition region, and wherein the magnetic resonance apparatus has scan means configured to execute the scan such that a flip angle of an RF pulse of the imaging sequences of the first to i-th times gradually increases.

7. The magnetic resonance apparatus according to claim 6, wherein values of “i” in at least two segments in the plurality of segments are different from each other.

8. The magnetic resonance apparatus according to claim 6, wherein the k space has a line crossing the data acquisition region and the data non-acquisition region, and wherein data acquired by the imaging sequences of the first to i-th times in each of the segments is disposed on the line.

9. The magnetic resonance apparatus according to claim 8, wherein data acquired by the imaging sequences of the j-th and subsequent times (where j>i) in each of the segments is disposed on the line so as to be arranged from a first position in the data acquisition region toward a second position on a side of the data acquisition region opposite to the data non-acquisition region, and wherein the scan means is configured to execute the scan such that the flip angle of the RF pulse of the imaging sequences of the j-th and subsequent times gradually decreases.

10. The magnetic resonance apparatus according to claim 9, wherein values of “j” in at least two segments in the plurality of segments are different from each other.

11. The magnetic resonance apparatus according to claim 6, wherein the sequence group has a navigator sequence for detecting a respiratory signal of the subject.

12. The magnetic resonance apparatus according to claim 11, wherein the navigator sequence is executed after a wait time which is provided after execution of the imaging sequences of the plurality of times.

13. The magnetic resonance apparatus according to claim 6, wherein maximum values of flip angles of at least two segments in the plurality of segments are different from each other.

14. A magnetic resonance apparatus configured to:
divide k space into a data acquisition region in which data is acquired and a data non-acquisition region in which data is not acquired; and
execute a scan including a sequence group in which an imaging sequence is executed a plurality of times, thereby acquiring data disposed in the data acquisition region, wherein data acquired by imaging sequences of j-th and subsequent times (where j>1) in the imaging sequences of the plurality of times is disposed in the data acquisition region so as to be arranged from a position in the data acquisition region toward a position on a side of the data acquisition region adjacent to the data non-acquisition region, and wherein the magnetic resonance apparatus has scan means configured to execute the scan such that a flip angle of an RF pulse of the imaging sequences of the j-th and subsequent times gradually decreases.

15. The magnetic resonance apparatus according to claim 14, wherein the k space has a line crossing the data acquisition region and the data non-acquisition region, and wherein data acquired by the imaging sequences of the j-th and subsequent times is disposed on the line.

16. The magnetic resonance apparatus according to claim 15, wherein data acquired by the imaging sequences of the first to i-th times (where i<j) in the imaging sequences of the plurality of times is disposed on the line so as to be arranged in a direction toward the data non-acquisition region from a position on the side of the data acquisition region opposite to the data non-acquisition region, and wherein the scan means is configured to execute the scan such that the flip angle of the RF pulse of the imaging sequences executed for the first time to the i-th time gradually increases.

17. The magnetic resonance apparatus according to claim 14, wherein the sequence group has a navigator sequence for detecting a respiratory signal of a subject.

18. The magnetic resonance apparatus according to claim 17, wherein the navigator sequence is executed after a wait time which is provided after execution of the imaging sequences of the plurality of times.

19. A magnetic resonance apparatus configured to:
divide k space into a data acquisition region in which data is acquired and a data non-acquisition region in which data is not acquired; and
execute a scan including a sequence group in which an imaging sequence is executed a plurality of times, thereby acquiring data disposed in the data acquisition region, wherein the imaging sequences of the plurality of times are divided in a plurality of segments, wherein data acquired by imaging sequences of the j-th (where j>1) and subsequent times in each segment is disposed in the data acquisition region so as to be arranged toward a first position on a side of the data acquisition region adjacent to the data non-acquisition region from a second position in the data acquisition region, and wherein the apparatus has scan means configured to execute the scan such that a flip angle of an RF pulse of the imaging sequences of the j-th and subsequent times gradually decreases.

20. The magnetic resonance apparatus according to claim 19, wherein values of “j” in at least two segments in the plurality of segments are different from each other.

21. The magnetic resonance apparatus according to claim 19, wherein the k space has a line crossing the data acquisition region and the data non-acquisition region, and wherein data acquired by the imaging sequences of the j-th and subsequent times in each of the segments is disposed on the line.

22. The magnetic resonance apparatus according to claim 21, wherein data acquired by the imaging sequences of the first to i-th times (where i<j) in each of the segments is disposed on the line so as to be arranged in a direction toward the data non-acquisition region from a position on the side of the data acquisition region opposite to the data non-acquisition region, and wherein the scan means is configured to execute each of the segments so that the flip angle of the RF pulse of the imaging sequences of the first to i-th times gradually increases.

23. The magnetic resonance apparatus according to claim 22, wherein values of “i” in at least two segments in the plurality of segments are different from each other.

24. The magnetic resonance apparatus according to claim 19, wherein the sequence group has a navigator sequence for detecting a respiratory signal of a subject.

25. The magnetic resonance apparatus according to claim 24, wherein the navigator sequence is executed after a wait time which is provided after execution of the imaging sequences of the plurality of times.

26. The magnetic resonance apparatus according to claim 19, wherein maximum values of flip angles of at least two segments in the plurality of segments are different from each other.
